(19) United States
(12) Patent Application Publication
(10) Pub. No.: US 2005/0155742 A1
(43) Pub. Date: Jul. 21, 2005

(54) Heat sink combining assembly

(75) Inventor: Tian-Yuan Lai, Sanchung City (TW)

Correspondence Address: BACON & THOMAS, PLLC, 625 SLATERS LANE, FOURTH FLOOR, ALEXANDRIA, VA, 22314, US

(73) Assignee: KOCAM INTRNATIONAL CO., LTD., SANCHUNG CITY (TW)

(21) Appl. No.: 10/760,341

(22) Filed: Jan. 21, 2004

(51) Int. Cl. H05K 7/20

(52) U.S. Cl. 165/80.3; 361/704

(57) ABSTRACT

The present invention discloses a heat sink combining assembly, which comprises a plurality of metallic heat dispersing fins and a fixing bar, wherein each metal heat dispersing fin at its top surface has a groove, and a securing hole is disposed in the groove for connecting the metallic heat dispersing fins to constitute an accommodating channel. Each fixing bar is installed in each accommodating channel, and the embedding section at the top of the connected structure is used to latch into each securing hole in the same row. Such arrangement can assemble the metallic heat dispersing fins to form a heat sink assembly quickly.

### FIELD OF THE INVENTION

The present invention relates to a heat sink assembly, more particularly to a heat sink assembly that can combine several heat dispersing fins together by fixing bars.

### BACKGROUND OF THE INVENTION

As the development of information technology is blooming these days, information products for computers not only develop in a very fast pace, but also bring us convenience and improvements which is definitely indispensable to our daily life. In recent years, the population of computer users is increasing day after day, consumers are having higher and higher demand on computers, not just asking for the features of lightness, thinness, shortness, and compactness, but also demanding high-speed computation, high reliability, high component density, and low price. With these requirements, it is necessary to have a fast central processing unit (CPU). However, increasing the speed of CPU will also increase the heat produced by the CPU operations. Therefore, heat dispersion becomes a major issue for computer systems.

As the performance of CPUs keeps growing together with the development of computers and semiconductor process technologies in the industry, the CPU speed becomes faster and faster. In addition, the density of transistors in the CPU is also increased. Therefore, the consuming power gets larger and larger, and the heat generated by such CPU also becomes amazingly high. The CPUs at early time did not need heat sinks at all, but the present CPUs may be burned if a heat sink is not used. Therefore, the ways of lowering the surface temperature during CPU operations to avoid a system crash due to overheat and effectively maintaining a normal operation for computers become an important issue nowadays.

Further, with the high demand of e-Commerce applications, computer system manufacturers is facing a substantial change because the personal computer not only requires a fast computational speed and a high storage capacity, of which personal computers are regarded as a sever architecture for being turned on all the time, but also plays the roles or system administration, external connection, and data access. Therefore, the stability of the computer is very important, and a system crash due to an overheated CPU is definitely not allowed. It is thus a big challenge for the computer industry to effectively achieve the heat dispersing effect. In other words, if we want to develop a fast data processing computer system, the heat dispersion problem of the CPU must be solved first. Further, the heat dispersion for memories is also a subject for the computer industry to make improvements.

There are many different ways of connecting a heat sink. Please refer to FIG. 1 for a heat sink assembly 6, which includes a plurality of heat dispersing fins 60 mutually connected with one other in sequence, each heat dispersing fin.60 comprises a main plate 601 and two corresponding horizontal sections 602, and the horizontal sections 602 extended from both ends of the main plate 601 and perpendicular to the main plate 601. Each horizontal section 602 comprises a latch groove 621. A protrusion is extended from the front side of the latch groove 621 and a latch member 623 is disposed on the protrusion 622, so that the latch groove 621 and the latch member 623 of the protrusion 622 can be used to connect the adjacent heat dispersing fins 60 to form a heat sink assembly 6.

However, most designs of the heat sink have too many latch grooves or securing holes, which make the manufacturing process too complicated and increase the overall manufacturing cost. The speed of assembling a heat sink assembly is very slow. From the standpoint of cost- effectiveness, the win-win situation for both the manufacturers and the consumers is to provide an equivalent or even better heat sink assembly with the possible lowest cost and fastest assembling speed. Such heat sink not only brings convenience to consumers, but also breaks through the traditional designs in the information industry.

### SUMMARY OF THE INVENTION

In view of the prior art as described above, it is not difficult to find out that the central processing unit, also known as the heart of computer, is a main mathematical and logical operation unit. Regardless of addition, subtraction, multiplication, division, or operations for complicated multimedia instructions, all these computational operations are carried out in the CPU. Therefore, the speed of a CPU is usually regarded as the index of the computer system. From the history and the evolution of the CPU, it is obvious that a breakthrough in the CPU technology accompanies a new generation of computers. As a result, the operational temperature of a CPU gets very high. In view of this situation and all kinds of shortcomings of the current heat sinks (such as high cost and slow assembling speed, etc), the inventor of this invention conducted extensive researches and developments and experiments, and finally invented the heat sink combining assembly in accordance with the present invention, which contributes to the public by its innovative ideas.

The primary objective of the present invention is to provide a heat sink combining assembly with a high heat dispersion rate, a simple structure, a low cost, and a fast assembling speed. The main structure comprises a plurality of metallic heat dispersing fins and a fixing bar, wherein each metal heat dispersing fin at its top surface has a groove, and a securing hole is disposed in the groove to sequentially connect the metallic heat dispersing fins to constitute an accommodating channel. Each fixing bar is installed in each accommodating channel, and the embedding section at the top of the connected structure is used to latch into each securing hole in the same row. Such arrangement can assemble the metallic heat dispersing fins to form a metal heat assembly quickly.

### BRIEF DESCRIPTION OF THE DRAWINGS

FIG. 1 is a view illustrating the connection of heat dispersing fins according to a prior-art heat sink.

FIG. 2 is a perspective view of a heat sink according to the present invention.

FIG. 3 is a planar view of a heat sink according to the present invention.

FIG. 4 is a cross-sectional view of a heat sink according to the present invention.

FIG. 5 is a cross-sectional view of a heat sink according to another preferred embodiment of the present invention.

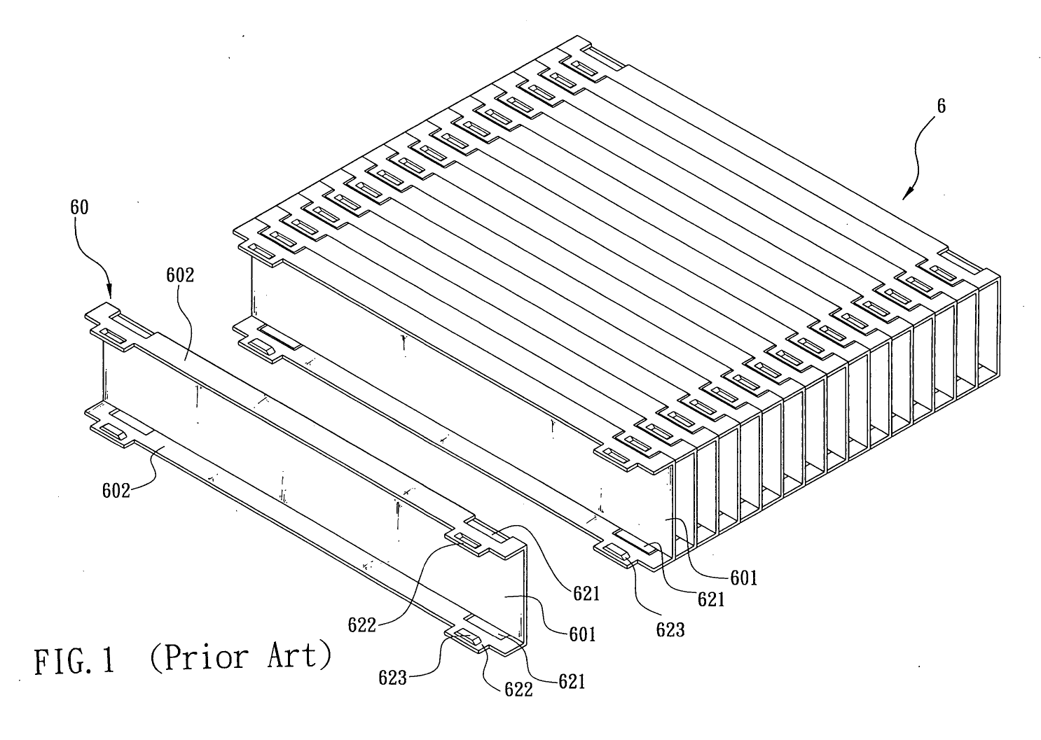

### DETAILED DESCRIPTION OF THE PREFERRED EMBODIMENTS

To make it easier for our examiner to understand the objective of the invention, its structure, innovative features, and performance, we use a preferred embodiment together with the attached drawings for the detailed description of the invention.

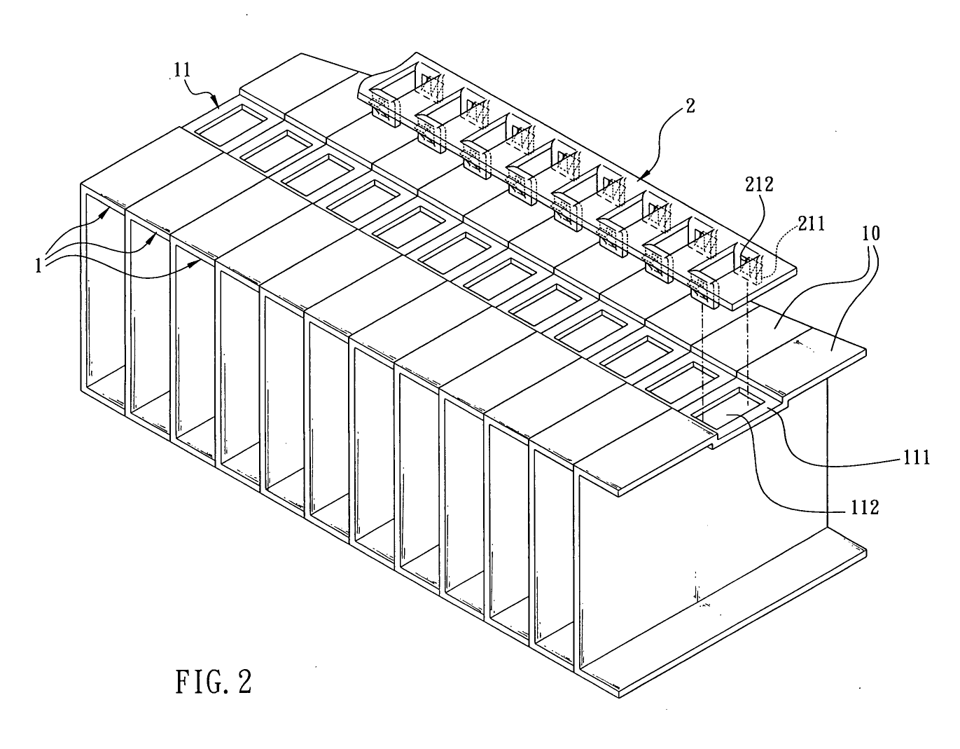

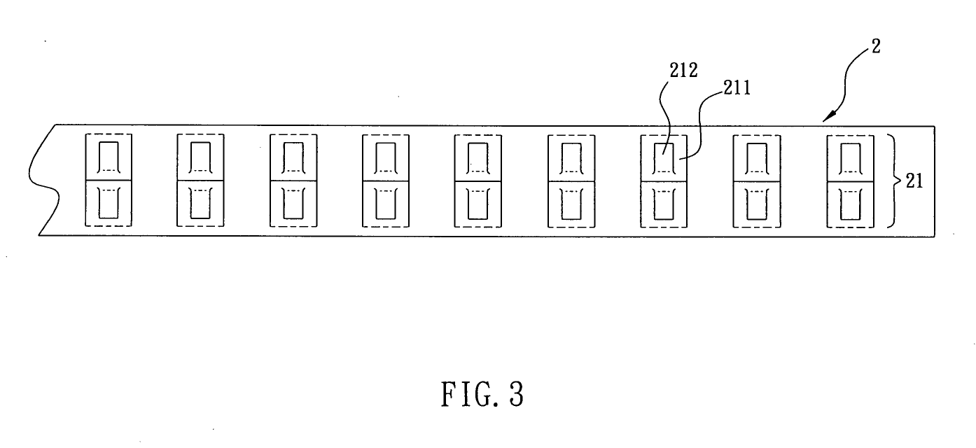

Please refer to FIG. 2 for a heat sink combining assembly, which comprises a plurality of metallic heat dispersing fins 1 and at least one fixing bar 2, wherein a top surface 10 of the metallic heat dispersing fin 1 includes at least a groove 111 and a securing hole 112 in each groove 111, such that when the metallic heat dispersing fins 1 are connected sequentially in adjacent to one another, the grooves 111 are connected to constitute an accommodating channel 11 and the securing holes 112 at the corresponding positions at the top surface 10 or same height are aligned linearly with each other. Therefore, each fixing bar 2 can be installed into each accommodating channel 11, and the embedding section 21 at the top of the assembled structure (as shown in FIG. 3) is used to latch into each securing hole 112 in the same row as to connect the metallic heat dispersing fins to form a heat sink assembly quickly.

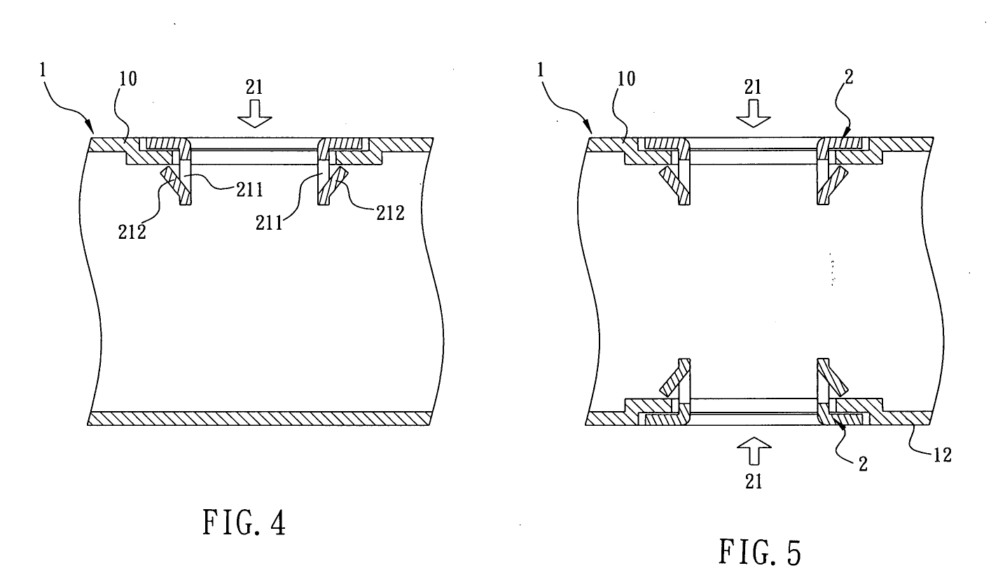

Please refer to FIGS. 2 to 4 for a preferred embodiment of this invention. Each embedding section 21 comprises two downwardly bent latch plates 211, each having a securing plate 212, wherein each securing plate 212 is outwardly bent to an appropriate angle, so that when each fixing bar 2 is installed into each securing hole 112 in the same row, the two securing plates 212 on each latch plate 211 are inserted into the securing holes 112 in the same row. The two securing plates 212 on each latch plate 211 are used to latch in the opposite direction onto the inner surface of each metallic heat dispersing fin 1, and each fixing bar 2 is fixed into each accommodating channel 11 to constitute the heat sink assembly by connecting the metallic heat dispersing fins 1 together.

Please refer to FIG. 5 for another preferred embodiment of this invention. To reinforce the connection of the overall heat sink assembly, each metallic heat dispersing fin 1 further includes a bottom plate 12 disposed at a position corresponding to the top surface 10 and having at least one second groove 111, and a second securing hole 112 in the second groove 111. When the metallic heat dispersing fins 1 are connected sequentially adjacent to each other, the second grooves 111 are connected to form an accommodating channel 11. The second securing holes 112 at the corresponding positions on the bottom plates 12 are aligned with each other linearly. Therefore, each fixing bar 2 can be installed in each securing hole 112, and a second embedding section 21 disposed on the fixing bar 2 is used to latch each second securing hole 112 in the same row and serially connect the metallic heat dispersing fins 1 to constitute a heat sink assembly.

Please refer to FIG. 2 of the embodiments of this invention. The metallic heat dispersing fin 1 has three faces, which are connected adjacent to each other and bent to an angle of 90 degrees. Further, the metallic heat dispersing fin 1 is also a hollow rectangular box with 5 faces.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

1. A heat sink combining assembly, comprising:
a plurality of metallic heat dispersing fins, each having at least one groove at its top surface, and each groove having a securing hole, such that when said metallic heat dispersing fins being coupled sequentially adjacent with one another, said grooves defining a successive accommodating channel and said each securing hole at the corresponding position on said top surface being aligned linearly with each other; and
at least one fixing bar, being installed into said accommodating channel in the same row to latch each embedding section on said fixing bar into said each securing hole, so that said metallic heat dispersing heat sink fins being serially coupled with one another to form said heat sink assembly.

2. The heat sink combining assembly of claim 1, wherein said embedding section comprises two corresponding downwardly bent latch plates, and said each latch plate has a securing plate outwardly bent to an appropriate angle, so that when said each fixing bar is installed into said accommodating channel to insert said two latch plates on said embedding section into said each securing hole in the same row, said each securing plate of said two latch plates is used to latch in the opposite direction onto the inner surface of said each metallic heat dispersing fin to connect said metallic heat dispersing fins to define said heat sink assembly.

3. The heat sink combining assembly of claim 1, wherein said metallic heat dispersing fin has three faces being connected with one another and bent to an angle of 90 degrees.

4. The heat sink combining assembly of claim 1, wherein said metallic heat dispersing fin is in the shape of a hollow rectangular box with 5 faces.

5. The heat sink combining assembly of claim 1, wherein said metallic heat dispersing fin further comprises a bottom plate disposed at a position corresponding to said top surface.

6. The heat sink combining assembly of claim 5, wherein said bottom plate comprises at least a second groove and a second securing hole in said second groove, and said metallic heat dispersing fins are aligned sequentially and coupled with one another to define a second accommodating channel, and said each second securing hole at the corresponding positions on said bottom plates are aligned linearly with each other, such that when said each fixing bar is installed into said accommodating channel, said second embedding section is latched into said each securing hole in the same row to serially connect said metallic heat dispersing fins to define said heat sink assembly.

7. The heat sink combining assembly of claim 6, wherein said second embedding section comprises two corresponding downwardly bent second latch plates, each having a second securing plate being outwardly bent into an appropriate angle.

8. The heat sink combining assembly of claim 7, wherein said each fixing bar is installed into said second accommodating channel, said each second latch plate is inserted into said second securing hole in the same row, and latched in the opposite direction into the inner side of said each metallic heat dispersing fin to connect said metallic heat dispersing fins to define said heat sink assembly.
